(19) United States
(12) Patent Application Publication
(10) Pub. No.: US 2022/0165530 A1
(43) Pub. Date: May 26, 2022

(54) ELECTRONIC FUSE (E-FUSE) WITH DISPLACEMENT-PLATED E-FUSE TERMINALS

(71) Applicant: Microchip Technology Incorporated, Chandler, AZ (US)

(72) Inventor: Yaojian Leng, Portland, OR (US)

(73) Assignee: Microchip Technology Incorporated, Chandler, AZ (US)

(21) Appl. No.: 17/233,367

(22) Filed: Apr. 16, 2021

Related U.S. Application Data
(60) Provisional application No. 63/116,265, filed on Nov. 20, 2020.

(51) Int. Cl. H01H 85/06; H01L 23/525; H01H 69/02

(52) U.S. Cl. CPC H01H 85/06; H01L 21/76807; H01H 69/02; H01L 23/5256

(57) ABSTRACT

An electronic fuse (e-fuse) module may be formed in copper interconnect in an integrated circuit device. A pair of e-fuse terminals may be formed by forming a pair of spaced-apart e-fuse terminal structures (e.g., copper damascene structures) and forming a conductive barrier region on each e-fuse terminal structure. The barrier regions may be formed by displacement plating a conductive barrier layer, e.g., comprising CoWP, CoWB, Pd, CoP, Ni, Co, or Ni—Co alloy, on each e-fuse terminal structure. An e-fuse element, e.g., comprising NiCr, TiW, TiWN, or Al, may be formed on the barrier regions of the pair of e-fuse terminals to define a conductive path between the pair of e-fuse terminal structures through the e-fuse element and through the barrier region on each e-fuse terminal structure. The barrier regions may protect the e-fuse terminal structures (e.g., copper structures) from corrosion and/or diffusion.

### RELATED APPLICATION

This application claims priority to commonly owned U.S. Provisional Patent Application No. 63/116,265 filed Nov. 20, 2020, the entire contents of which are hereby incorporated by reference for all purposes.

### TECHNICAL FIELD

The present disclosure relates to electronic fuses (e-fuses) formed in integrated circuit (IC) devices, for example e-fuse modules formed in an interconnect, and methods for manufacturing such e-fuse modules.

### BACKGROUND

A fuse is a resistive link, which can be permanently programmed between a low resistance state and a high resistance state. An e-fuse uses electric current (as opposed to laser) to cause the change of resistance (programming) from the low resistance state (e.g. less than 1 Kohm) to the high resistance state (e.g. greater than 100 Kohn). E-fuses are useful in a wide range of applications, for example (a) for protection from electrostatic discharge (ESD) during manufacture and handling, (b) for removing or replacing a defective device from a circuit, (c) for programming one-time programmable memory, for example ROM (Read Only Memory), OTP (One Time Programmable memory), or PROM (Programmable Read Only Memory), without limitation, (d) for electronic digital trim of passive components (e.g., resistors, capacitors, or inductors), or (e) to provide chip security by preventing unauthorized access.

In the integrated circuit industry, the predominant type of e-fuse is the salicide polysilicon e-fuse, in which a silicide region formed on the polysilicon forms a low resistance path before programming, and is purposefully destroyed by high current during programming, which changes the fuse to the high resistance state. FIGS. 1A and 1B show a top view and side cross-sectional view, respectively, of a conventional polysilicon e-fuse 100. As shown, the polysilicon e-fuse 100 includes a polysilicon silicide fuse element contacted by tungsten terminals. The polysilicon silicide fuse element may be programmed through electro migration, wherein a large current, for example 10 mA, is driven through the polysilicon silicide fuse element, which ruptures the polysilicon silicide fuse element and thereby switches the fuse from a low resistance state to a high resistance state.

However, the polysilicon e-fuse is not available in certain high-k dielectric and metal gate transistor technology. In contrast to polysilicon e-fuse, an e-fuse formed of metal is generally preferred due to its low melting point and ease of programming using electromigration. Thus, in some advanced CMOS designs, interconnect metal or via is used as an e-fuse without introducing a dedicated e-fuse metal, through thermally accelerated metal electromigration. However, this process is typically very complicated and requires specialized programming because only some parts of the circuit (components associated with the e-fuse) are programmed by electromigration, while other parts of the circuit (e.g., normal CMOS components) must be protected from electromigration.

To increase programming margin and overall device reliability associated with integrated e-fuses formed of metal, there is a need for improved e-fuses with a dedicated e-fuse metal that can be fabricated cheaply, reliably, and with high density.

For example, there is a need for e-fuse modules formed in copper interconnect, for integration with common IC manufacturing processes. However, using copper interconnect for e-fuse modules presents particular challenges. For example, copper diffuses fast during and/or after interconnect structure manufacturing, which may form deep-level traps and substantially degrade transistor performance. Thus, copper may be encased in a barrier layer to prevent or inhibit such diffusion. A dielectric (non-conductive) barrier layer of silicon nitride (SiN) or silicon carbide (SiC) is commonly formed over copper structures after a copper chemical mechanical polishing (CMP). However, this dielectric barrier formed over the copper structures presents a challenge for connecting an e-fuse element (film) formed of metal to a pair of copper structures (e-fuse terminals). In addition to the challenge of copper diffusion, copper is also susceptible to corrosion. Thus there is a need for e-fuses, formed of metal, constructed in a copper interconnect structure protected against copper diffusion and corrosion. Further, there is a need to reduce or minimize the number of mask layers needed to construct such integrated e-fuses.

### SUMMARY

Embodiments of the present disclosure provide e-fuses formed of metal that may be integrated in IC devices in a modular manner, thus referred to herein as “e-fuse modules.” For example, some embodiments provide e-fuse modules formed in copper damascene interconnect structures of IC devices, and methods for manufacturing such e-fuse modules. The e-fuse modules can be formed at any level of interconnect (e.g., at any metal layer) in the IC device structure.

In some embodiments an e-fuse module incudes a pair of e-fuse terminals each including an e-fuse terminal structure (e.g., copper damascene structure) and a conductive barrier region formed on top of the e-fuse terminal structure (e.g., to protect the metal from corrosions and/or diffusion) and an e-fuse element formed on and bridging the conductive barrier regions, to thereby conductively connect the e-fuse terminal structures to each other. In some embodiments, the conductive barrier regions may be formed by displacement plating a suitable material on each e-fuse terminal structure (e.g., copper damascene structure). Such conductive barrier regions may be referred to as “displacement-plated barrier regions.” The conductive barrier regions may both (a) provide a reliable conductive contact between the e-fuse element and e-fuse terminal structures (e.g., copper damascene structures) and (b) protect upper surfaces of the e-fuse terminal structures from corrosion and diffusion (e.g., coper corrosion and diffusion) during and after the manufacture of the e-fuse module. In some embodiments the conductive barrier regions may comprise cobalt tungsten phosphide (CoWP), which may be particularly suitable for the features discussed above. In other embodiments the conductive barrier regions may comprise Pd, CoP, CoWB, Ni, Co, Ni—Co alloy, or any other suitable material.

In other embodiments, the conductive barrier regions on each e-fuse terminal structure may be formed by another process, i.e., other than displacement plating. For example, a layer of conductive barrier material (e.g., Ta/TaN) may be deposited over the pair of e-fuse terminal structures and etched to define a discrete conductive barrier region on each e-fuse terminal structure.

In some embodiments an e-fuse module as disclosed herein may provide a resistance in the range of 100 ohms to 1,000 ohms, e.g., about 500 ohms, in a low resistance state, and a resistance in the range of 100 KΩ/and 100 MΩ, e.g., about 1 MΩ in a high resistance state. In some embodiments, the e-fuse module may have a resistance in the range of 300-500Ω in the low resistance state, and a resistance of greater than 1 MΩ in the high resistance state.

One aspect provides a method of manufacturing an electronic fuse (e-fuse) module in an integrated circuit (IC) structure. A pair of e-fuse terminals may be formed by forming a pair of e-fuse terminal structures spaced apart from each other in a dielectric region, and forming a barrier region on each e-fuse terminal structure, wherein the barrier region is formed of a conductive material. An e-fuse element may be formed on the pair of e-fuse terminals to define a conductive path connecting the pair of e-fuse terminal structures through the e-fuse element and through the barrier region on each metal e-fuse terminal structure.

In some embodiments, the barrier region on each e-fuse terminal structure may be formed by displacement plating. For example, each barrier region may be formed by displacement plating cobalt tungsten phosphide (CoWP).

In other embodiments, the barrier region on each e-fuse terminal may be formed by depositing a barrier layer and selectively etching areas of the deposited barrier layer.

In some embodiments, the e-fuse terminal structures are formed using a damascene process. For example, the e-fuse terminal structures may comprise Cu damascene structures.

In some embodiments, the e-fuse element fully covers a top area of each e-fuse terminal. In another embodiments, the e-fuse element covers only a partial portion of a top area of each e-fuse terminal.

In one embodiment, the e-fuse film includes (a) a pair of terminal regions, each covering a top area of one of the e-fuse terminals and (b) a connecting region connecting the pair of terminal regions, the connecting region having a smaller width than the terminal regions.

In one embodiment, the method includes forming a plurality of transistors prior to forming the pair of e-fuse terminal structures, and forming the pair of e-fuse terminal structures in contact with the plurality of transistors.

In some embodiments, the e-fuse element comprises NiCr, TiW, TiWN, or Al.

Another aspect provides an IC structure including an e-fuse module including a pair of spaced-apart e-fuse terminals, and an e-fuse element formed on the pair of spaced-apart e-fuse terminals. Each e-fuse terminal includes a barrier region formed on a respective e-fuse terminal structure, where the barrier region is formed of a conductive material. The e-fuse element formed on the pair of spaced-apart e-fuse terminals define a conductive path connecting the pair of e-fuse terminal structures through the e-fuse element and through the barrier region at the top of each metal e-fuse terminal structure.

In some embodiments, the barrier region at the top of each e-fuse terminal structure comprises a displacement-plated barrier region.

In some embodiments, the barrier region at the top of each e-fuse terminal structure comprises cobalt tungsten phosphide (CoWP).

In some embodiments, the e-fuse terminal structures are formed using a damascene process. For example, the e-fuse terminal structures may comprise Cu damascene structures.

In some embodiments, the e-fuse element fully covers a top area of each e-fuse terminal. In another embodiments, the e-fuse element covers only a partial portion of a top area of each e-fuse terminal.

In one embodiment, the e-fuse film includes (a) a pair of terminal regions, each covering a top area of one of the e-fuse terminals and (b) a connecting region connecting the pair of terminal regions, the connecting region having a smaller width than the terminal regions.

Another aspect provides an IC structure including an e-fuse module and a first interconnect structure. The e-fuse module may include (a) a pair of spaced-apart e-fuse terminals, each including an e-fuse terminal structure formed in a first metal layer and a barrier region formed on the e-fuse terminal structure, and (b) an e-fuse element formed on the spaced-apart e-fuse terminals to define a conductive path connecting the pair of e-fuse terminal structures through the e-fuse element and through the barrier region at the top of each metal e-fuse terminal. The first interconnect structure may include an interconnect trench element formed in the first metal layer, and a barrier region formed on the interconnect trench element.

In some embodiments, the barrier region formed on each e-fuse terminal structure and the barrier region formed on the interconnect trench element each comprise a displacement-plated barrier region.

In some embodiments, the barrier region formed on each e-fuse terminal structure and the barrier region formed on the interconnect trench element each comprise CoWP.

In some embodiments, the pair of e-fuse terminal structures and the interconnect trench element comprise copper damascene structures.

In one embodiment, the IC structure also includes an e-fuse film region formed on the barrier region formed on the interconnect trench element and spaced apart from the e-fuse element, wherein the e-fuse film region and the e-fuse element are formed from a common e-fuse film.

In some embodiments, the e-fuse element comprises NiCr, TiW, TiWN, or Al.

In one embodiment, the IC structure includes a second metal layer including a second interconnect trench element connected to the first interconnect structure by an interconnect via.

### BRIEF DESCRIPTION OF THE DRAWINGS

Example aspects of the present disclosure are described below in conjunction with the figures, in which:

FIGS. 1A and 1B shows a top view and side cross-sectional view, respectively, of a conventional polysilicon e-fuse;

FIG. 2 illustrates an example integrated circuit structure including an e-fuse module along with a nearby interconnect structure, formed according to an example embodiment of the present disclosure;

FIGS. 3A-8 show an example process for forming an example e-fuse module and nearby interconnect structure in an integrated circuit, according to one example embodiment; and

FIGS. 9A-10B show an alternative embodiment for forming an example e-fuse module and nearby interconnect structure, wherein the photomask used to form the e-fuse element covers only a selected area over the e-fuse terminals, according to one example embodiment.

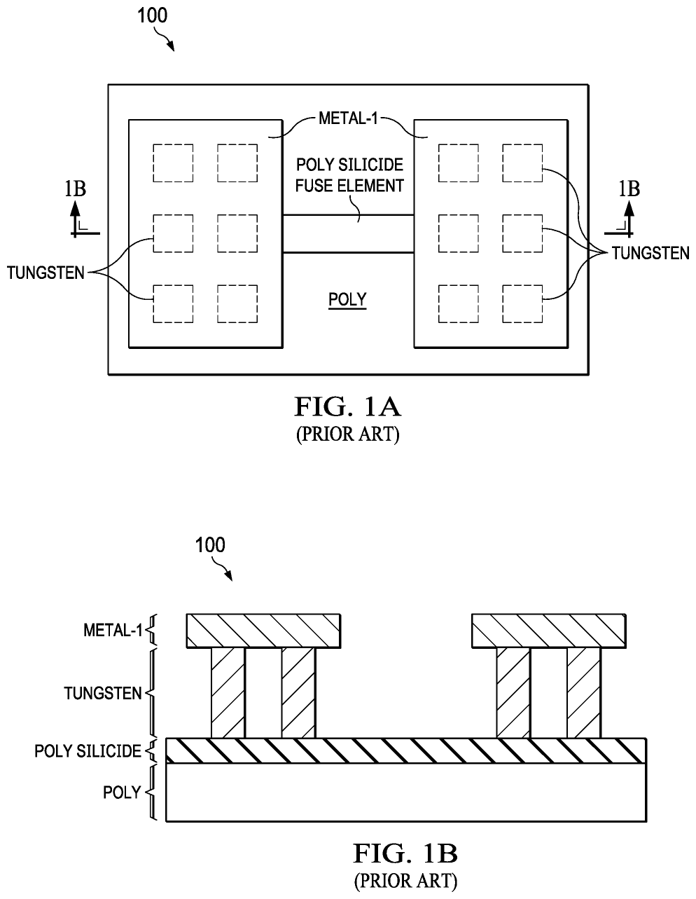

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

Embodiments of the present disclosure provide e-fuse modules formed in copper interconnect. In some embodiments, an e-fuse module incudes a pair of e-fuse terminals each including an e-fuse terminal structure (e.g., copper damascene structure) and a barrier region formed on top of the e-fuse terminal structure (e.g., to protect the metal from corrosions and/or diffusion), where the barrier region is conductive, and an e-fuse element formed on and bridging the conductive barrier regions, to thereby conductively connect the e-fuse terminal structures to each other.

Statements and references herein regarding a displacement-plated barrier region providing protection against copper corrosion and diffusion mean the displacement-plated barrier region provides at least a partial barrier against copper corrosion and diffusion. For example, the disclosed displacement-plated barrier regions may provide functional reliability for the relevant device (e.g., e-fuse module or device including the e-fuse module) over a 10 year period at normal device operating temperatures (−40° C. to 125° C.).

In some embodiments the barrier regions are formed by displacement plating a barrier material on each e-fuse terminal structure to define a pair of displacement-plated e-fuse terminals, and the e-fuse element is formed on the pair of displacement-plated e-fuse terminals. Each displacement-plated e-fuse terminal may include a displacement-plated barrier region formed on a copper e-fuse terminal structure, e.g., a Cu damascene trench structure formed in a Cu interconnect layer. The e-fuse element formed on the displacement-plated e-fuse terminals provide a conductive path connecting the pair of Cu e-fuse terminal structures through the e-fuse element and through the displacement-plated barrier regions. The barrier regions may both (a) provide a conductive contact between the e-fuse element and e-fuse terminal structures and (b) protect upper surfaces of the e-fuse terminal structures during the manufacture of the e-fuse module. In some embodiments the barrier region may comprise CoWP, CoWB, Pd, CoP, Ni, Co, Ni—Co alloy, or any other suitable material. Although the present disclosure focuses on embodiments formed in Cu interconnect, in other embodiments the e-fuse module may be formed in damascene interconnect of other metals, for example iridium (Ir), rhodium (Rh), ruthenium (Ru), or cobalt (Co).

In other embodiments, the barrier regions on the e-fuse terminal structures may be formed by another process. For example, a layer of barrier material (e.g., Ta/TaN) may be deposited over the pair of e-fuse terminal structures and etched to define a discrete barrier region on each e-fuse terminal structure.

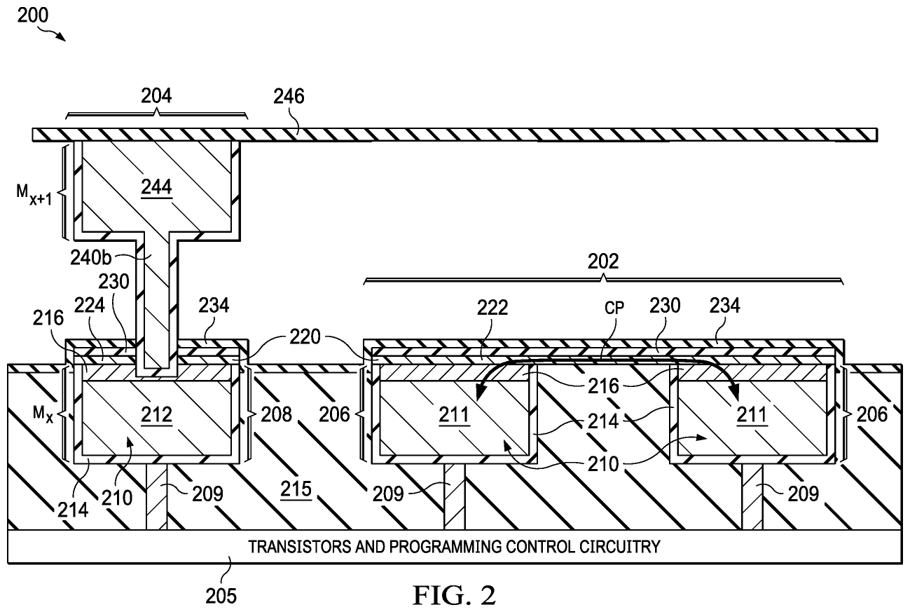

FIG. 2 illustrates an example IC structure 200 including an e-fuse module 202 along with a nearby interconnect structure 204, formed according to one embodiment of the present disclosure. As shown, the e-fuse module 202 includes an e-fuse element 222 connecting a pair of e-fuse terminals 206 with each other, and the interconnect structure 204 may include (among other elements) a lower interconnect structure 208 and an upper interconnect structure 244.

E-fuse terminals 206 and lower interconnect structure 208 may each comprise a trench element 210, which trench element 210 may be formed of Cu, formed in a common metal interconnect layer Mₓ (where x refers the level of interconnect metal in the IC structure 200), at any depth in the IC structure 200. In some embodiments, e.g., where the e-fuse module 202 is used for programming by a group of transistors, it may be beneficial to form the e-fuse module 202 as close as possible to the transistors, to drive the required program current (e.g., 1-10 mA) to “burn” the e-fuse element without causing negative side effects, for example voltage drop due to interconnect resistance, Joule heating, or electromigration. Thus, in some embodiments the e-fuse terminals 206 may be formed in the metal 1 layer (x=1) or metal 2 layer (x=2).

In particular, the trench elements 210 define a pair of e-fuse terminal structures 211, and a lower interconnect element 212. Each trench element 210 may be formed over a barrier layer 214 (e.g., a Ta/TaN bilayer) deposited in a respective trench formed in a dielectric region 215. In some embodiments, the trench elements 210 may be formed by a Cu damascene process in which the barrier layer material (e.g., Ta/TaN bilayer), followed by copper, are deposited and plated over the dielectric region 215 and extending down into the trench openings formed in the dielectric region 215, followed by a chemical mechanical polishing (CMP) process to remove unwanted copper at the top of the structure.

The e-fuse terminals 206 and lower interconnect structure 208 may be formed over and electrically connected to various IC circuitry 205, e.g., including transistors and programming control circuitry, by respective contact vias 209 formed prior to the e-fuse terminal structures 211 and lower interconnect structure 208.

As shown, a barrier region 216, which is conductive and thus may be referred to as “conductive barrier region 216,” may be formed on each trench element 210. In some embodiments, barrier regions 216 may be formed by displacement plating a top surface of each trench element 210 (e.g., after the CMP discussed above) with a conductive material at the top of each trench element 210, in which case barrier region 216 may be referred to as “displacement-plated barrier region 216.” For example, a barrier region 216 of CoWB, Pd, CoP, Ni, Co, Ni—Co alloy, or any other suitable metal may be displacement-plated on each trench element 210 (e.g., Cu damascene trench element).

In other embodiments, barrier regions 216 may be formed by depositing a layer of conductive barrier material over the pair of e-fuse terminal structures and etching the barrier material layer to define a discrete barrier region 216 on each e-fuse terminal structure, in which case barrier region 216 may be termed “discrete barrier region 216.” The conductive barrier material may comprise any conductive material suitable to prevent or inhibit corrosion and/or diffusion of the underlying e-fuse terminal structures (e.g., Cu damascene structures), for example, Ta/TaN, TiN, or TiW.

The barrier regions 216 formed on e-fuse terminal structures 211 define a conductive path between the e-fuse element 222 and the Cu e-fuse terminal structures 211, as indicated by the double-headed arrow CP in FIG. 2.

In addition, the barrier regions 216 may protect each trench element 210 during and after the remaining construction of the e-fuse module 202 and interconnect structure 204, e.g., to prevent or reduce corrosion and/or diffusion of trench elements 210, which may be important for the resulting reliability of the e-fuse module 202 and interconnect structure 204. Thus, the barrier regions 216 may be formed from material(s) suitable for both (a) providing an effective electrical contact (e.g., having a contact resistance less than 1 ohm) between the e-fuse element 222 and e-fuse terminal structures 211 and (b) protecting trench elements 210 (including e-fuse terminal structures 211 and lower interconnect element 212) from corrosion and diffusion (e.g. copper corrosion and copper diffusion), e.g., during and after the manufacturing of the IC structure 200. For example, the barrier regions 216 may provide a device reliability of over 10 years under normal operating conditions (e.g., normal operating temperatures). In some embodiments, the barrier regions 216 may comprise CoWP, found to be particularly suitable for the properties discussed above. Other suitable materials for the barrier region 216 may include CoWB, Pd, CoP, Ni, Co, Ni—Co alloy, or other suitable material.

Barrier regions 216 may be formed with a specified or target thickness, whether formed by displacement plating or by a deposition and etch process as disclosed above. For example, barrier regions 216 may be formed with a thickness that is (a) sufficiently thick to provide an effective barrier against corrosion and/or diffusion and also to allow effective control of the plating/deposition process for barrier regions 216, but (b) relatively thin relative to the underlying trench elements 210, as the barrier regions 216 are typically less conductive than the underlying trench elements 210 (e.g., copper) and may thus reduce the effectiveness of the various conductive components, e.g., interconnect structure 204. Thus, in some embodiments, barrier regions 216, whether formed by displacement plating or by a deposition and etch process as disclosed above, may be formed with a vertical thickness in the range of 100 Å-300 Å, for example about 200 Å.

As discussed in more detail below, the e-fuse element 222 may be formed by (a) depositing an e-fuse film 220, e.g., comprising NiCr, TiW, TiWN, or Al, over the e-fuse terminals 206 and lower interconnect structure 208, and (b) patterning the e-fuse film 220 to define (i) the e-fuse element 222 bridging the e-fuse terminals 206 and (ii) an e-fuse film region 224 over the lower interconnect structure 208. An e-fuse cap 230 (e.g., comprising silicon nitride or silicon oxide) may be formed over the e-fuse film 220, and an optional dielectric barrier layer 234 may be formed over the e-fuse cap. The dielectric barrier layer 234 may be optional, e.g., depending on (a) the suitability of underlying layers (including the barrier regions 216) to act as a copper diffusion barrier, (b) etch stop requirements for building the next level of interconnect structure, as defined by the particular design specification, and/or other relevant considerations. For example, in some embodiments e-fuse cap 230 is formed from SiN and provides an additional copper diffusion barrier and etch stop layer, such that the dielectric barrier layer 234 may be omitted.

Lower interconnect structure 208 may connect to interconnect circuitry in other metal layer(s). For example, in the example shown in FIG. 2, the lower interconnect structure 208 may be connected to an upper interconnect structure 244 formed in a metal layer Mₓ₊₁ by an interconnect via 240b. In the illustrated embodiment, upper interconnect structure 244 and via 240b are formed as a Cu dual damascene structure. A dielectric barrier layer 246 may be formed over metal layer Mₓ₊₁.

In some embodiments, e-fuse element 222 may comprise NiCr, TiW, TiWN, or Al with a thickness in the range of 50 Å-1000 Å, which may provide a sheet resistance Rs in the range of 10-1000 Ω/square. In the low resistance state, the e-fuse element 222 may have a resistance in the range of 100 ohms to 1,000 ohms, e.g., about 500 ohms, and in the high resistance state a resistance in the range of 100 Ω/and 100 MΩ, e.g., about 1 MΩ. In some embodiments, the e-fuse module may have a resistance in the range of 300-500Ω in the low resistance state, and a resistance of greater than 1 MΩ in the high resistance state.

Although metal layers Mₓ and Mₓ₊₁ may comprise copper as discussed above, in other embodiments metal layer Mₓ and/or Mₓ₊₁ (and thus trench elements 210 and/or upper interconnect element 242) may be formed from other metal(s), for example Iridium (Ir), Rhodium (Rh), Ruthenium (Ru), or Cobalt (Co). The various barrier layers, e.g., barrier regions 216, the optional dielectric barrier layer 234, and/or dielectric barrier layer 246 may be adjusted accordingly, i.e. the constituent elements thereof, based on the selected interconnect metal.

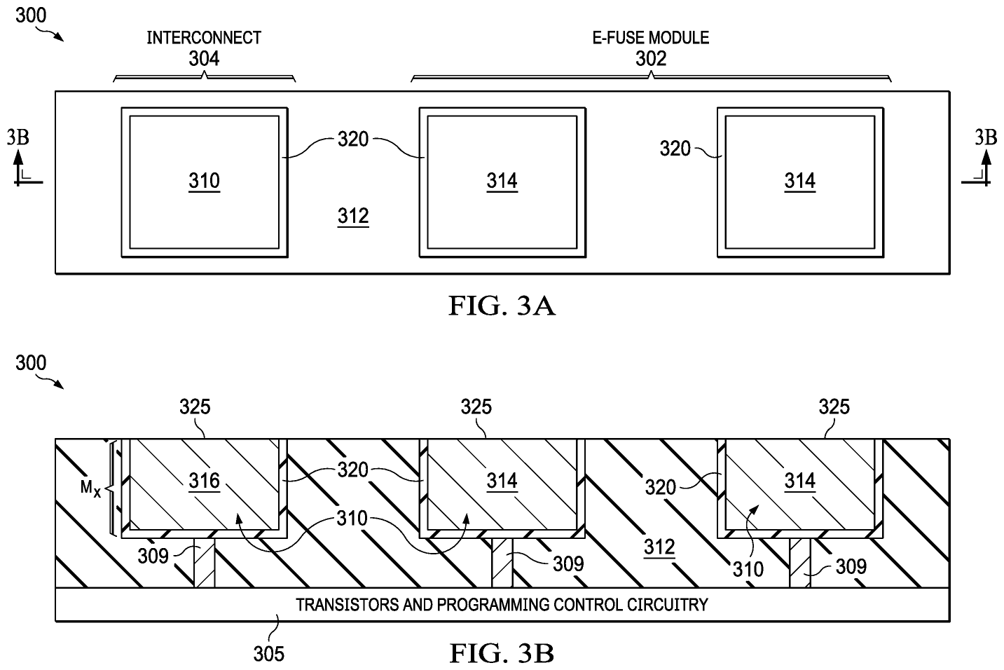

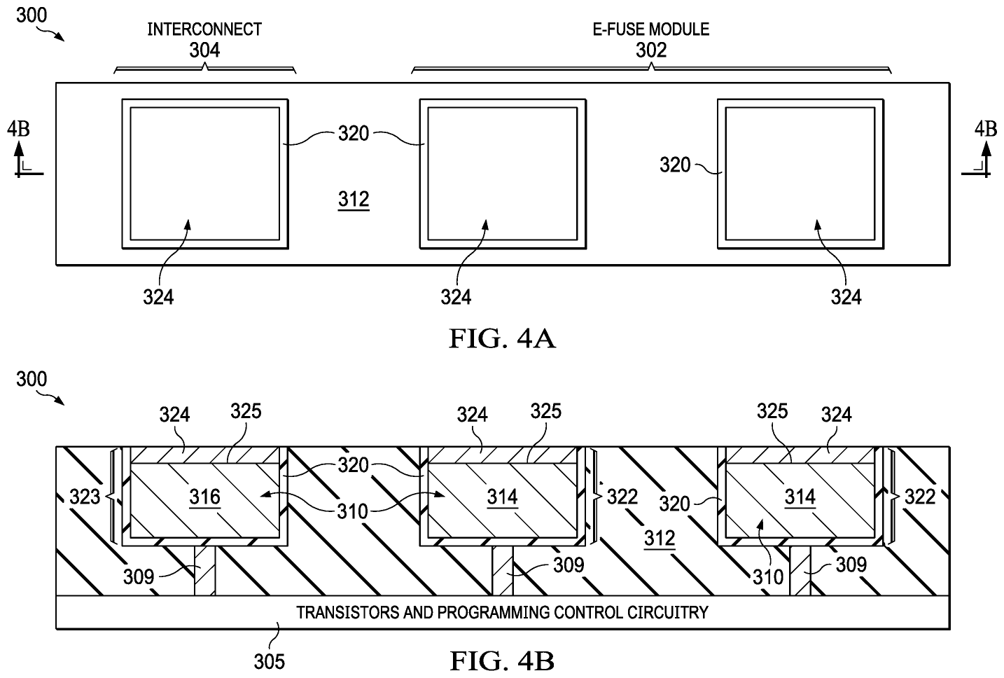

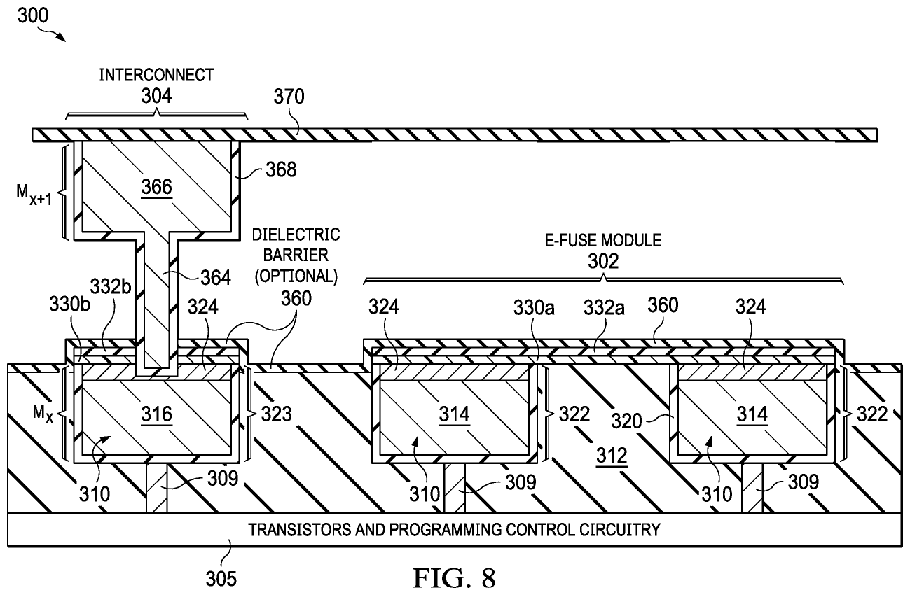

FIGS. 3A-8 show an example process for forming an e-fuse module 302 along with a nearby interconnect structure 304 in an example IC structure 300, according to one embodiment of the present disclosure. E-fuse module 302 and interconnect structure 304 formed according to the process shown in FIGS. 3A-8 may correspond with e-fuse module 202 and interconnect structure 204, respectively, shown in FIG. 2. Each pair of figures sharing the same figure number, namely FIGS. 3A and 3B, FIGS. 4A and 4B, FIGS. 5A and 5B, FIGS. 6A and 6B, and FIGS. 7A and 7B, shows a similar top view and a cross-sectional side view, respectively, of the example IC structure 300 being constructed, in which the cross-sectional side view is taken through a cut line indicated in the top view. For example, FIG. 3B shows a cross-sectional side view taken through line 3B-3B shown in the top view FIG. 3A, FIG. 4B shows a cross-sectional side view taken through line 4B-4B shown in the top view FIG. 4A, etc. FIG. 8 shows a cross-sectional side view of the completed e-fuse module 302 and interconnect 304.

As shown in FIGS. 3A and 3B, the IC structure 300 may include trench elements 310 formed in metal layer Mₓ in a dielectric region 312 formed above IC circuitry 305, e.g., including transistors and programming control circuitry. Trench elements 310 may define (a) a pair of e-fuse terminal structures 314 for the e-fuse module 302 being constructed and (b) a lower interconnect element 316 for the interconnect structure 304. Trench elements 310 may be connected to selected IC circuitry 305, e.g., by respective contact vias 309 formed prior to the trench elements 310. In one example embodiment trench elements 310 are formed of Cu.

Each trench element 310 may be formed over a barrier layer 320 (e.g., a Ta/TaN bilayer) deposited in a respective trench opening. In one embodiment, the trench elements 310 may be formed by a Cu damascene process in which Cu is deposited over dielectric region 312 and extends down into trench openings formed in dielectric region 312, followed by CMP process to remove unwanted Cu at the top of the structure. Dielectric region 312 may include one or more dielectric materials, e.g., at least one silicon oxide, fluorosilicate glass (FSG), organosilicate glass (OSG), porous OSG, or other low-k dielectric material, e.g., having a dielectric constant less than 4.

After the CMP process, an exposed top surface 325 of each trench element 310 is typically susceptible to oxidation, for example from the oxygen in the air, moisture in the air, or water residue left from a post CMP clean. Exposure to light may further accelerate such oxidation or corrosion process. Such corrosion can result in yield loss and reliability failure of the resulting IC device. Thus, it may be beneficial to protect the upper surface of each trench element 310 soon after the CMP to reduce this corrosion risk.

Thus, as shown in FIGS. 4A and 4B, a barrier region 324 of conductive material may be formed on each trench element 310 (including each e-fuse terminal structure 314 and lower interconnect element 316), to thereby define e-fuse terminals 322 and a lower interconnect structure 323. The barrier region 324 may protect each trench element 310 (e.g., Cu damascene trench element) from corrosion and/or diffusion. In some embodiments, barrier regions 324 may be formed by displacement plating the top surface 325 of each trench element 310 with a conductive material, by an electroless plating (displacement plating) process, to form a displacement-plated barrier region 324 on each trench element 310. For example, a barrier region 324 of CoWB, Pd, CoP, Ni, Co, Ni—Co alloy, or any other suitable metal may be displacement-plated on each trench element 310.

In other embodiments, barrier regions 324 may be formed by depositing a layer of conductive barrier material over the structure, thus covering the top surfaces 325 of trench elements 310 and top surfaces of dielectric region 312, and etching the barrier material layer (e.g., at locations between the various trench elements 310) to define a discrete barrier region 325 on each trench element 310 (including each e-fuse terminal structure 314 and lower interconnect element 316). The conductive barrier material may comprise any conductive material suitable to prevent or inhibit corrosion and/or diffusion of the underlying trench elements 310 (e.g., Cu damascene structures), for example, Ta/TaN, TiN, or TiW.

The barrier region 324 formed at the top of each trench element 310 may (a) protect the top surface 325 of the trench element 310 from copper corrosion, e.g., during construction of the e-fuse module 302 and interconnect structure 304, and (b) reduce diffusion from the trench element 310, e.g., into underlying or neighboring silicon, which may improve reliability performance. In addition, the barrier regions 324 formed on each e-fuse terminal structure 314 may provide an effective electrical contact (e.g., contact resistance of less than 1 ohm) between the respective e-fuse terminal structure 314 and an overlying e-fuse element 330a (discussed below).

Using a displacement plating process to form barrier regions 324 on each trench element 310, as disclosed above, allows for selective formation of a metal diffusion barrier on each trench element 310, but not on the areas of dielectrics region 312 between the trench elements 310. This may be advantageous over other techniques for forming a separate barrier region over trench element 310, for example the disclosed process of depositing a layer of barrier material (e.g., Ta/TaN layer) over the full wafer and etching selected areas (e.g., between the various trench elements 310), which may involve additional process steps and thus additional cost as compared with a displacement plating process.

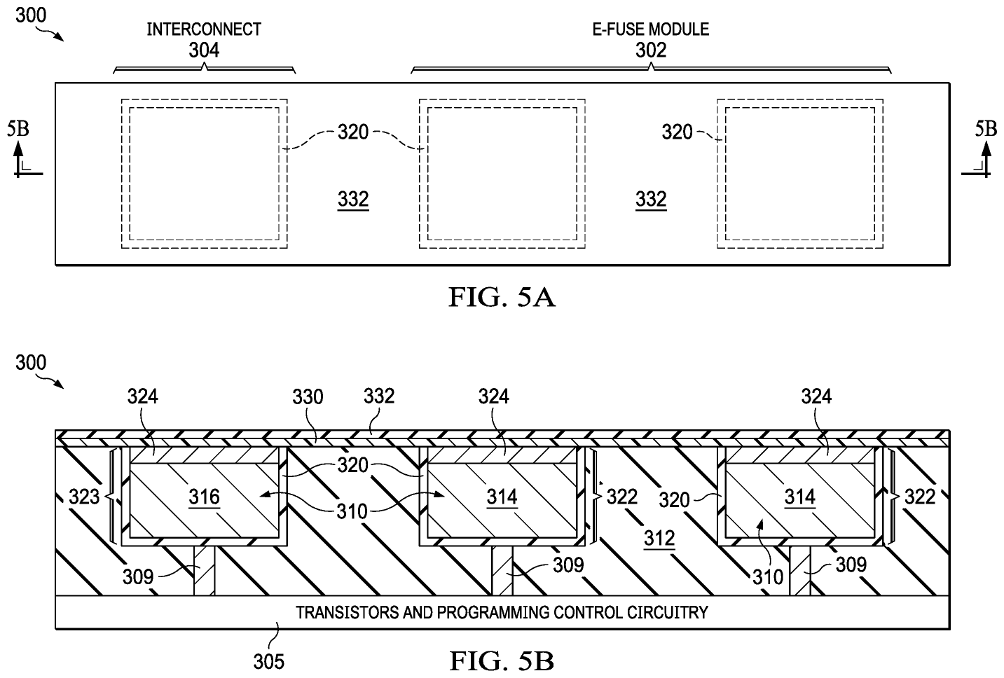

Next, as shown in FIGS. 5A and 5B, an e-fuse film 330 is deposited over the structure, followed by a dielectric cap layer 332. The e-fuse film 330 may be formed directly onto the e-fuse terminals 322 and lower interconnect structure 323. E-fuse film 330 may include any suitable e-fuse film material, such as nichrome (NiCr), titanium tungsten (TiW), titanium tungsten nitride (TiWN), aluminum (Al), or other suitable metal or metal alloy, and may be deposited by physical vapor deposition (PVD) or other suitable deposition technique.

The dielectric cap layer 332 may be formed to protect the underlying e-fuse film 330 during construction of the e-fuse module 302, for example, to protect the e-fuse film from an oxidation during an ash process (photoresist removal step), which may affect the performance of the resulting e-fuse module 302. The dielectric cap layer 332 may comprise silicon nitride, silicon oxide, or other suitable cap material to protect the e-fuse film 330, and may be deposited by chemical vapor deposition (CVD) or other suitable deposition technique.

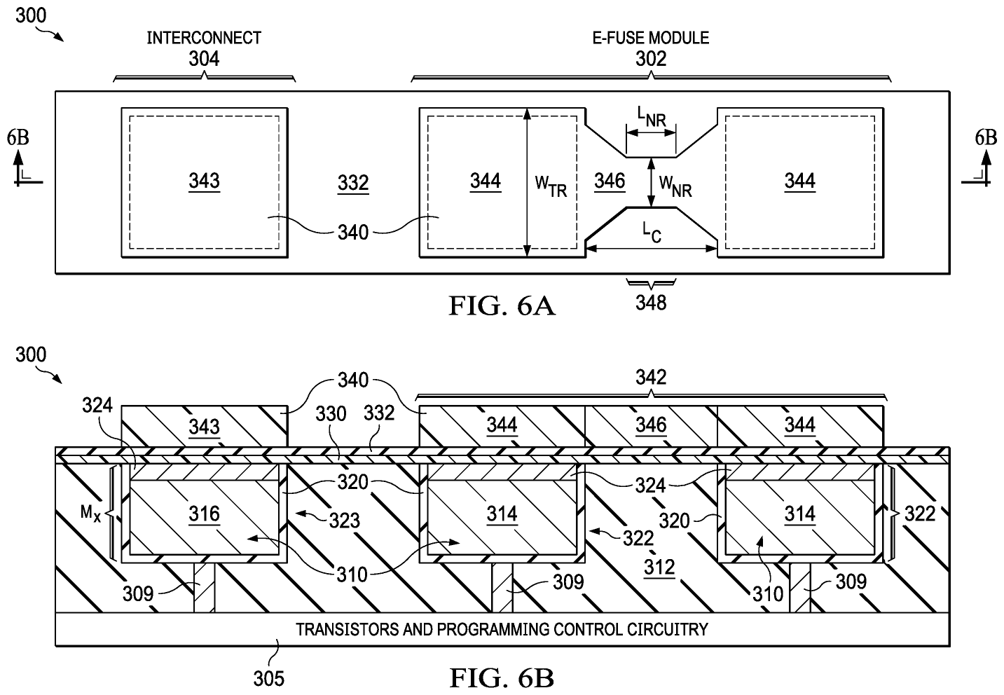

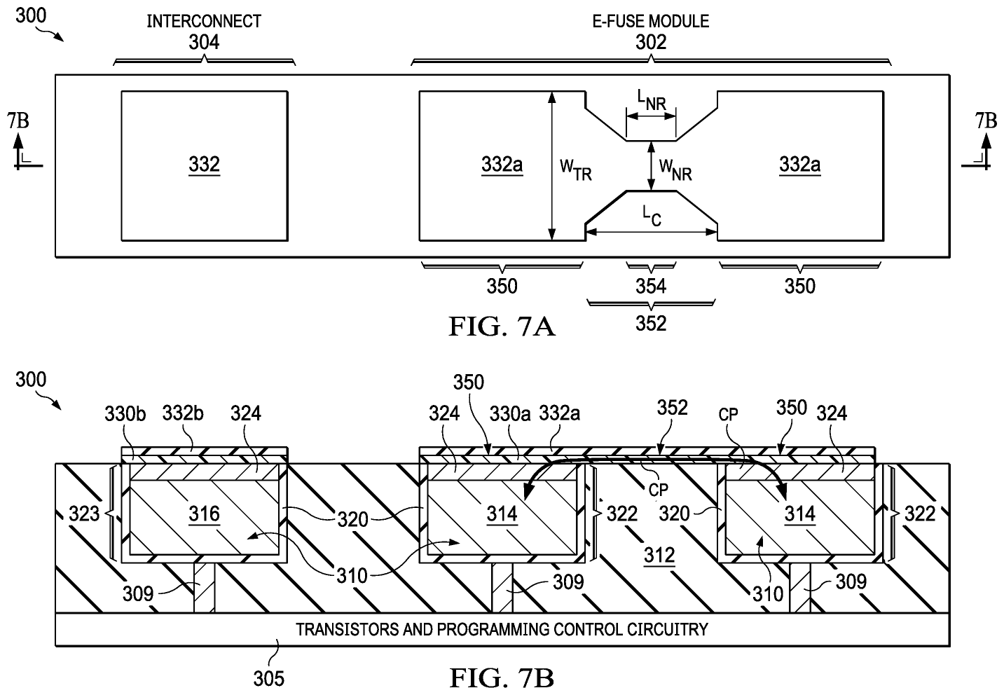

Next, as shown in FIGS. 6A and 6B, a photoresist mask (photomask) 340 is formed and patterned over the dielectric cap layer 332. The patterned photomask 340 may include (a) an e-fuse patterning region 342 including a respective terminal region 344 over each e-fuse terminal 322 and a connecting region 346 connecting the two terminal regions 344, and (b) an interconnect patterning region 343 covering the lower interconnect structure 323. The connecting region 346 may have a narrowed, high-resistance “neck” portion 348 that defines a bowtie or hourglass shape of the connecting region 346. A width W_{NR} of the neck portion 348 may be less than a width W_{TR} of each terminal region 344, for example less than 90%, less than 75%, less than 60%, less than 50%, less than 30%, or less than 20% the width W_{TR} of each terminal region 344. The width W_{NR} of the neck portion 348, along with the length L_{NR} of the neck portion 348, the length L_{C} of the connecting region 346, and/or the particular shape of the connecting region 346 and neck portion 348, which define the corresponding shape and dimensions of the resulting post-etch e-fuse element 330a as shown in FIGS. 7A-7B discussed below, may be selected and/or adjusted to provide desired performance characteristics of the resulting e-fuse module 302, e.g., the resistance value and/or the point of “fusing” where the conductive path across the e-fuse is broken.

In this embodiment, the patterned photomask 340 fully covers the patterned copper layer Mₓ, or in other words, the patterned photomask 340 covers the full area (from the top view shown in FIG. 6A) of all metal structures in layer Mₓ on the wafer, including e-fuse terminals 322 and lower interconnect structure 323. Patterning the photomask 340 to fully cover the metal structures in metal layer Mₓ may provide various advantages, as compared with patterning only an area associated with the e-fuse module 302. For example, in a photolithography process in which the e-fuse pattern density is low (e.g., about 1%), the required photo exposure is typically very high, which may cause the lens to overheat, leading to unwanted process variation. By patterning a much larger percentage of the wafer area (i.e., to cover all of the metal structures in Mₓ layer), the required photo exposure may be substantially reduced, thus avoid potential lens overheating.

In addition, patterning the larger percentage of the wafer area may substantially reduce the subsequent plasma etch burden (by reducing the area to etch). In addition, the risk of plasma etch penetrating through the barrier regions 324 at the top of each trench element 310 may be reduced or eliminated. Moreover, by pattering the full copper layer Mₓ, the photomask may be generated in a straightforward manner, e.g., by first reverse tuning the mask used to form the trench layer Mₓ (e.g., by switching from glass to chrome or from chrome or glass), then performing a logic “OR” of the reverse tuned mask with the e-fuse module pattern.

Next, as shown in FIGS. 7A and 7B, an etch may be performed to remove portions of the dielectric cap layer 332 and underlying e-fuse film 330 in areas unprotected by the patterned photomask 340. In some embodiments, a plasma etch, or alternatively a wet etch, may be performed. A resist strip and clean process may be performed after the etch. The resulting portions of the dielectric cap layer 332 and e-fuse film 330 may define (a) an e-fuse element 330a and corresponding e-fuse dielectric cap 332a over the e-fuse terminals 322 and over a portion of dielectric region 312 therebetween, and (b) an e-fuse film cap 330b and dielectric cap 332b over the lower interconnect structure 323. The e-fuse element 330a includes (a) a terminal region 350 covering the full area of each e-fuse terminal 322 (corresponding with terminal regions 344 of patterned photomask 340 discussed above), and (b) a connecting region 352 that connects the two terminal regions 350, and including a narrowed neck portion 354 (corresponding with the connecting region 346 and neck region 348 of the patterned photomask 340 discussed above). As noted above, the various dimensions and shape of the connecting region 352, including the narrowed neck portion 354, may be selected and/or adjusted by controlling the dimensions and shape of the connecting region 346, including neck region 348, of the patterned photomask 340, to provide desired performance characteristics of the resulting e-fuse module 302, e.g., the resistance value and/or the point of “fusing” where the conductive path across the e-fuse is broken.

The e-fuse element 330a formed on the pair of e-fuse terminals 322 as disclosed above thereby defines a conductive path, indicated by double-headed arrow CP, between the two e-fuse terminal structures 314 through the barrier regions 324 and through the e-fuse element 330a. In some embodiments, e-fuse element 330a may comprise NiCr, TiW, TiWN, or Al with a thickness in the range of 50 Å-1000 Å, which may provide a sheet resistance Rs in the range of 10-1000 Ω/square. In some embodiments, the e-fuse element 330a may have a resistance in the range of 100 ohms to 1,000 ohms, e.g., about 500 ohms, in a low resistance state, and a resistance in the range of 100 KΩ/and 100 MΩ, e.g., about 1 MΩ in a high resistance state. In some embodiments, the e-fuse element 330a may have a resistance in the range of 300-500Ω in the low resistance state, and a resistance of greater than 1 MΩ in the high resistance state.

Next, as shown in the cross-sectional side view of FIG. 8, an optional additional dielectric barrier layer 360 may be deposited over the structure. The optional additional dielectric barrier layer 360 may be silicon nitride (SiN) or silicon carbide (SiC), without limitation. After depositing the optional dielectric barrier layer 360, interconnect formation may continue, to thereby contact the lower interconnect element 316. For example, lower interconnect element 316 may be contacted by an interconnect via 364 connected to a trench element 366. In the illustrated embodiment, trench element 366 and interconnect via 364 comprise a dual damascene Cu structure, e.g., formed by depositing a barrier layer 368 (e.g., a Ta/TaN bilayer), copper seed, and followed by copper plating, in a dual damascene trench. A copper CMP process is then performed to remove the excess copper. Finally, a dielectric barrier layer 370, e.g., comprising silicon nitride (SiN) or silicon carbide (SiC), without limitation, may be formed over metal layer Mₓ₊₁.

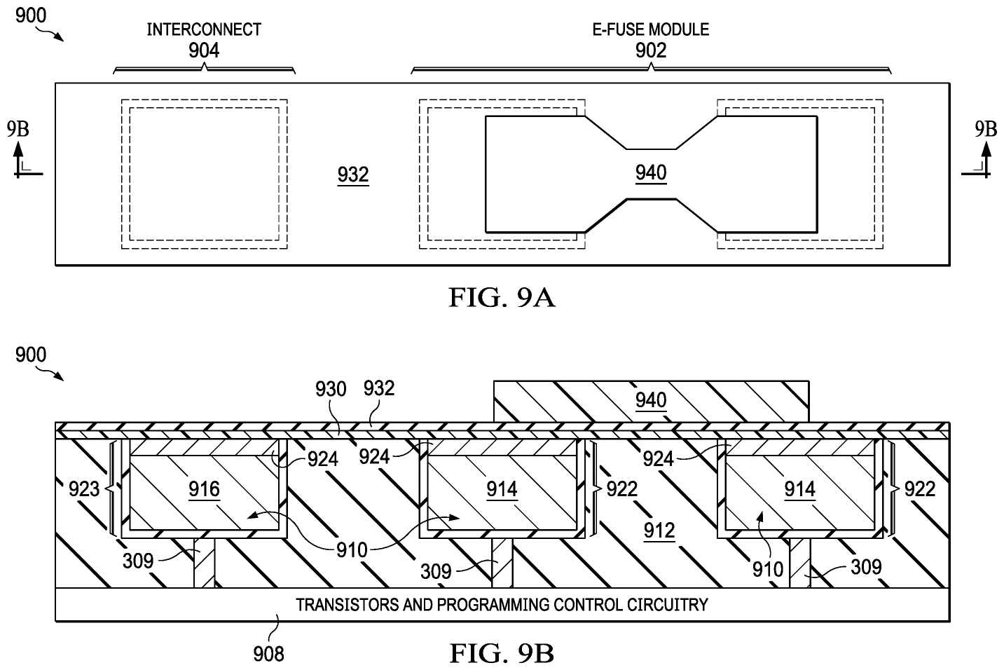

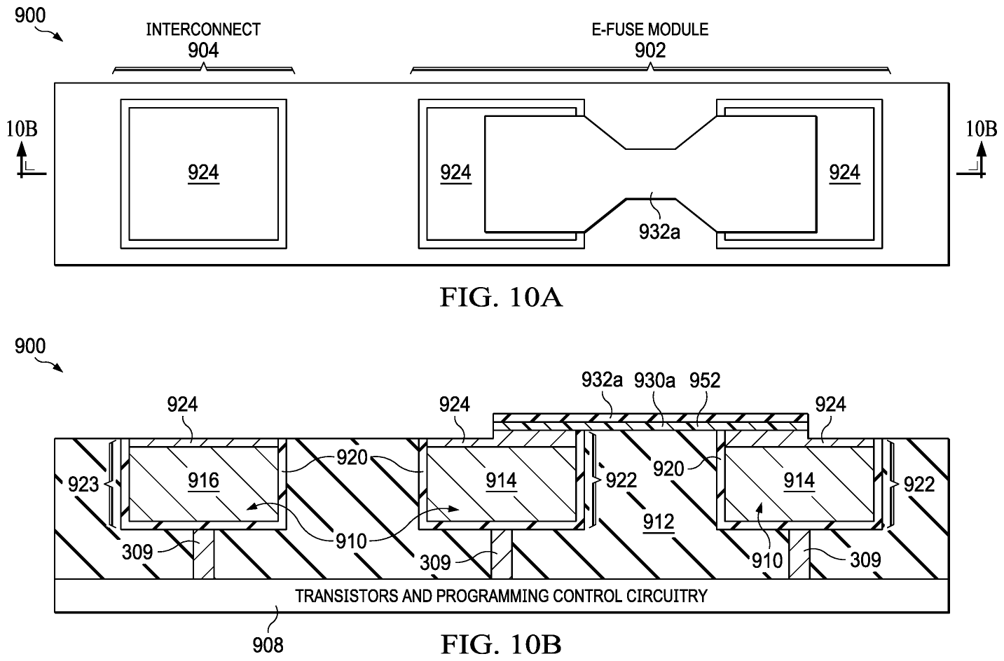

FIGS. 9A-9B and 10A-10B show an alternative embodiment in which the patterned photomask used to form the e-fuse element covers only a selected area over the e-fuse terminals, rather than covering all of the metal structures in metal layer Mₓ as shown in FIGS. 6A-6B and discussed above. First, FIGS. 9A and 9B show top view and a cross-sectional side view, of an example e-fuse module 902 and interconnect structure 904 being constructed in an example IC structure 900. The IC structure 900 may include trench elements 910 formed in metal layer Mₓ in a dielectric region 912. Trench elements 910 define (a) a pair of e-fuse terminal structures 914 for the e-fuse module 902 being constructed and (b) an interconnect element 916. A barrier region 924, e.g., comprising CoWP, Pd, CoP, CoWB, Ni, Co, Ni—Co alloy, or other suitable material, is formed on an upper region of each trench element 910, in one embodiment using displacement plating, to thereby define a pair of e-fuse terminals 922 and an interconnect structure 923. An e-fuse film 930, followed by a dielectric cap layer 932, are deposited over the structure. A photomask 940 is then formed and patterned over the dielectric cap layer 932.

Thus, the state of IC structure 900 shown in FIGS. 9A and 9B corresponds with the state of IC structure 300 shown in FIGS. 6A and 6B. However, unlike the patterned photomask 340 shown in FIGS. 6A and 6B that covers the full area of the e-fuse terminals 322 and lower interconnect structure 323, the patterned photomask 940 shown in FIGS. 9A and 9B covers only a partial area of the e-fuse terminals 922, and does not cover the interconnect structure 923.

FIGS. 10A-10B show a result of an etch (e.g., plasma etch or wet etch) using the patterned photomask 940 shown in FIGS. 9A and 9B. As shown, the etch forms an e-fuse element 930a and overlying e-fuse dielectric cap 932a that bridges the pair of e-fuse terminals 922. The etch may expose areas of barrier regions 924 and/or the underlying trench elements 910 (e.g., depending on the depth of the etch) in areas outside the patterned photomask 940. In some instances the etch may expose areas of the underlying trench elements 910, e.g., due to inherent variations in the etch process and the small thickness of the barrier regions 924 (e.g., about 100 Å), which may present a significant reliability risk for the resulting IC devices. Thus, in some embodiments, an additional dielectric barrier layer may be deposited over the structure, e.g., to provide protection against copper diffusion.

1-11. (canceled)

12. An integrated circuit structure, comprising:
an electronic fuse (e-fuse) module, comprising:
a pair of spaced-apart e-fuse terminals spaced apart from each other in a dielectric region, each of the e-fuse terminals comprising:
an e-fuse terminal structure formed in the dielectric region; and
a barrier region at a top of the e-fuse terminal structure;
an e-fuse element formed on the pair of spaced-apart e-fuse terminals to define a conductive path between the pair of e-fuse terminal structures through the e-fuse element and through the barrier region at the top of each metal e-fuse terminal structure.

13. The integrated circuit structure of claim 12, wherein the barrier region at the top of each e-fuse terminal structure comprises a displacement-plated barrier region.

14. The integrated circuit structure of claim 12, wherein the barrier region at the top of each e-fuse terminal structure comprises cobalt tungsten phosphide (CoWP).

15. The integrated circuit structure of claim 12, wherein the e-fuse terminal structures each comprise copper damascene structures.

16. The integrated circuit structure of claim 12, wherein the e-fuse element fully covers a top area of each e-fuse terminal.

17. The integrated circuit structure of claim 12, wherein the e-fuse element covers only a partial portion of a top area of each e-fuse terminal.

18. The integrated circuit structure of claim 12, wherein the e-fuse film includes (a) a pair of terminal regions, each covering a top area of one of the e-fuse terminals and (b) a connecting region connecting the pair of terminal regions, the connecting region having a smaller width than a width of each of the terminal regions.

19. An integrated circuit structure, comprising:
an electronic fuse (e-fuse) module comprising:
a pair of spaced-apart e-fuse terminals, each comprising:
an e-fuse terminal structure formed in a first metal layer; and
a barrier region formed on the e-fuse terminal structure; and
an e-fuse element formed on the pair of spaced-apart e-fuse terminals to define a conductive path connecting the pair of e-fuse terminal structures through the e-fuse element and through the barrier region formed on each e-fuse terminal structure; and
an interconnect structure comprising:
an interconnect element formed in the first metal layer; and
a barrier region formed on the interconnect element.

20. The integrated circuit structure of claim 19, wherein the barrier region formed on each e-fuse terminal structure and the barrier region formed on the interconnect trench element each comprise a displacement-plated barrier region.

21. The integrated circuit structure of claim 19, wherein the barrier region formed on each e-fuse terminal structure and the barrier region formed on the interconnect trench element each comprise cobalt tungsten phosphide (CoWP).

22. The integrated circuit structure of claim 19, wherein the pair of e-fuse terminal structures and the interconnect trench element comprise copper damascene structures.

23. The integrated circuit structure of claim 19, further comprising an e-fuse film region formed on the barrier region formed on the interconnect trench element and spaced apart from the e-fuse element, wherein the e-fuse film region and the e-fuse element are formed from a common e-fuse film.

24. The integrated circuit structure of claim 19, wherein the e-fuse element comprises NiCr, TiW, TiWN, or Al.
